(19) United States
(12) Patent Application Publication
(10) Pub. No.: US 2026/0075976 A1
(43) Pub. Date: Mar. 12, 2026

(54) PHOTODETECTION DEVICE AND ELECTRONIC APPARATUS

(71) Applicant: SONY SEMICONDUCTOR SOLUTIONS CORPORATION, Kanagawa (JP)

(72) Inventor: Tetsuya UCHIDA, Kanagawa (JP)

(73) Assignee: SONY SEMICONDUCTOR SOLUTIONS CORPORATION, Kanagawa (JP)

(21) Appl. No.: 19/108,693

(22) PCT Filed: Aug. 17, 2023
(86) PCT No.: PCT/JP2023/029672

§ 371 Date: Mar. 4, 2025

(30) Foreign Application Priority Data
Sep. 12, 2022 (JP) 2022-144731

(51) Int. Cl. H10F 39/00; H10F 39/18

(52) U.S. Cl. CPC H10F 39/811; H10F 39/014; H10F 39/182; H10F 39/8063

(57) ABSTRACT

A photodetection device according to an embodiment of the present disclosure includes: a semiconductor layer including a plurality of photoelectric conversion sections that performs photoelectric conversion on light; a pad that is provided on a first surface side of the semiconductor layer; a via that penetrates the semiconductor layer and is electrically coupled to the pad; and a first trench that is provided in such a manner that the first trench penetrates the semiconductor layer around the via to surround the via. The first trench is provided in such a manner that the first trenches form a lattice shape around the via in plan view.

### TECHNICAL FIELD

The present disclosure relates to a photodetection device and an electronic apparatus.

### BACKGROUND ART

There has been proposed a back side illuminated imaging device including an electrode pad for external electric connection and a pass-through portion that passes through a silicon layer and couples the electrode pad to wiring.

### CITATION LIST

### Patent Literature

Japanese Unexamined Patent Application Publication No. 2016-115757.

### SUMMARY OF THE INVENTION

It is desirable for devices that detect light to reduce unnecessary parasitic capacitance.

It is desired to provide a photodetection device that makes it possible to reduce such parasitic capacitance.

A photodetection device according to an embodiment of the present disclosure includes: a semiconductor layer including a plurality of photoelectric conversion sections that performs photoelectric conversion on light; a pad that is provided on a first surface side of the semiconductor layer; a via that penetrates the semiconductor layer and is electrically coupled to the pad; and a first trench that is provided in such a manner that the first trench penetrates the semiconductor layer around the via to surround the via. The first trench is provided in such a manner that the first trenches form a lattice shape around the via in plan view.

An electronic apparatus according to an embodiment of the present disclosure includes: an optical system; and a photodetection device that receives light passed though the optical system. The photodetection device includes: a semiconductor layer including a plurality of photoelectric conversion sections that performs photoelectric conversion on light; a pad that is provided on a first surface side of the semiconductor layer; a via that penetrates the semiconductor layer and is electrically coupled to the pad; and a first trench that is provided in such a manner that the first trench penetrates the semiconductor layer around the via to surround the via. The first trench is provided in such a manner that the first trenches form a lattice shape around the via in plan view.

### BRIEF DESCRIPTION OF THE DRAWINGS

FIG. 1 is a block diagram illustrating an example of a schematic configuration of an imaging device that is an example of a photodetection device according to an embodiment of the present disclosure.

FIG. 2 is a diagram illustrating an example of a pixel section of the imaging device according to the embodiment of the present disclosure.

FIG. 3 is a diagram illustrating a configuration example of a pixel of the imaging device according to the embodiment of the present disclosure.

FIG. 4 is a diagram illustrating an example of a cross-sectional configuration of the imaging device according to the embodiment of the present disclosure.

FIG. 5 is a diagram illustrating an example of a planar configuration of a portion of the imaging device according to the embodiment of the present disclosure.

FIG. 6A is a diagram illustrating an example of a method of manufacturing the imaging device according to the embodiment of the present disclosure.

FIG. 6B is a diagram illustrating the example of the method of manufacturing the imaging device according to the embodiment of the present disclosure.

FIG. 6C is a diagram illustrating the example of the method of manufacturing the imaging device according to the embodiment of the present disclosure.

FIG. 6D is a diagram illustrating the example of the method of manufacturing the imaging device according to the embodiment of the present disclosure.

FIG. 7 is a diagram illustrating an example of a cross-sectional configuration of an imaging device according to a first modification of the present disclosure.

FIG. 8 is a diagram illustrating an example of a cross-sectional configuration of an imaging device according to a second modification of the present disclosure.

FIG. 9 is a diagram illustrating another example of the cross-sectional configuration of the imaging device according to the second modification of the present disclosure.

FIG. 10 is a diagram illustrating another example of the cross-sectional configuration of the imaging device according to the second modification of the present disclosure.

FIG. 11 is a diagram illustrating another example of the cross-sectional configuration of the imaging device according to the second modification of the present disclosure.

FIG. 12 is a block diagram illustrating a configuration example of an electronic apparatus including the imaging device.

FIG. 13 is a block diagram depicting an example of schematic configuration of a vehicle control system.

FIG. 14 is a diagram of assistance in explaining an example of installation positions of an outside-vehicle information detecting section and an imaging section.

FIG. 15 is a view depicting an example of a schematic configuration of an endoscopic surgery system.

FIG. 16 is a block diagram depicting an example of a functional configuration of a camera head and a camera control unit (CCU).

### MODES FOR CARRYING OUT THE INVENTION

Next, with reference to drawings, details of embodiments of the present disclosure will be described. It is to be noted that the description will be given in the following order.
1. Embodiment
2. Modifications
3. Application Examples
4. Further Application Examples

### 1. Embodiment

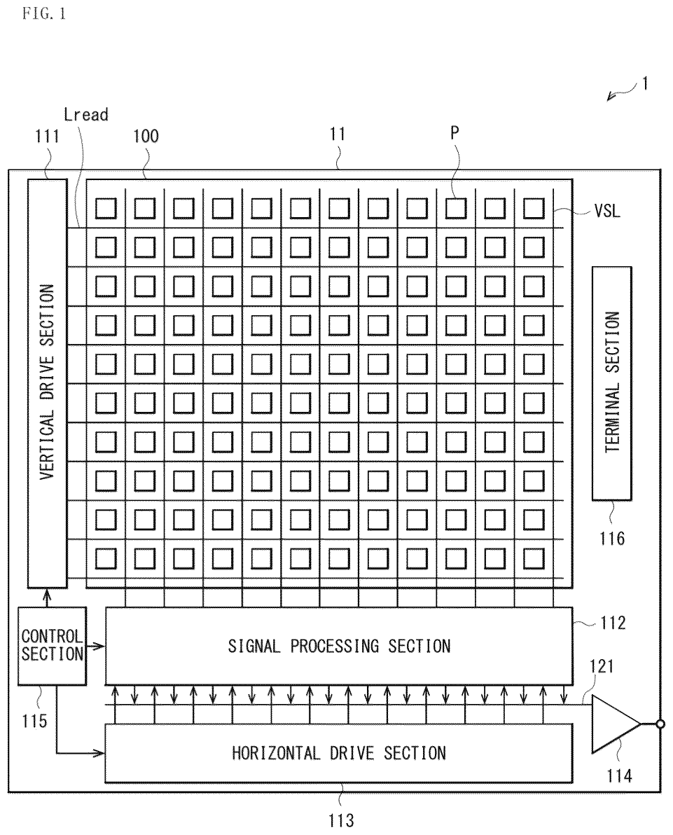

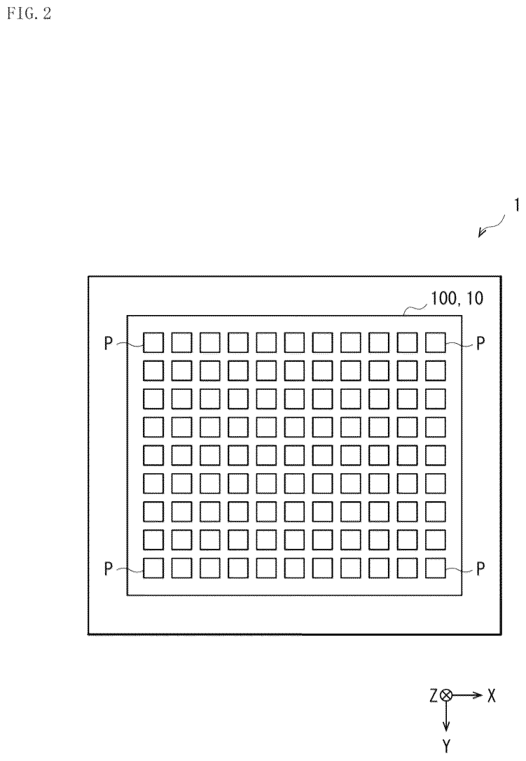

FIG. 1 is a block diagram illustrating an example of a schematic configuration of an imaging device that is an example of a photodetection device according to an embodiment of the present disclosure. FIG. 2 is a diagram illustrating an example of a pixel section of the imaging device according to the embodiment. The photodetection device is a device that makes it possible to detect incident light. The photodetection device may receive light passed through an optical system and generate a signal. An imaging device 1 serving as the photodetection device includes a plurality of pixels P having a photoelectric conversion section, and is configured to perform photoelectric conversion on incident light and generate a signal. The imaging device 1 may be applicable to image sensors, ranging sensors, and the Like.

The photodetection device according to the present disclosure may be applicable as a ranging sensor that makes it possible to measure a distance by using a time-of-flight (TOF) method. The photodetection device (imaging device 1) may be applicable as a sensor that makes it possible to detect events, such as an event-driven sensor (also referred to as an event-based vision sensor (EVS), a dynamic vision sensor (DVS), or the like).

The imaging device 1 includes the pixels P, each of which includes the photoelectric conversion section that is a photodiode and that makes it possible to perform photoelectric conversion on light. As illustrated in FIG. 2, the imaging device 1 includes an imaging area that is a region (pixel section 100) where the plurality of pixels P is two-dimensionally arranged in a matrix form.

The imaging device 1 takes in incident light (image light) from the subject via an optical system (not illustrated) including an optical lens. The imaging device 1 captures an image of the subject that is formed by the optical lens. The imaging device 1 performs photoelectric conversion on received light and generate a pixel signal. For example, the imaging device 1 is a complementary metal-oxide-semiconductor (CMOS) image sensor. The imaging device 1 is applicable to electronic apparatuses such as digital still cameras, video cameras, or mobile phones.

As illustrated in FIG. 2, it is to be noted that a Z-axis direction is an incident direction of light from a subject, an X-axis direction is a left-right direction that is orthogonal to the Z-axis direction on the paper surface, and a Y-axis direction is a top-bottom direction that is orthogonal to the Z-axis and the X-axis on the paper surface. With regard to subsequent drawings, sometimes directions may be described on the basis of the directions of the arrows illustrated in FIG. 2.

### Schematic Configuration of Imaging Device

As illustrated in the example in FIG. 1, for example, the imaging device 1 includes a vertical drive section 111, a signal processing section 112, a horizontal drive section 113, an output section 114, a control section 116, a terminal section 116, and the like in a region around the pixel section 100. The imaging device 1 is also provided with a plurality of pixel drive lines Lread and a plurality of vertical signal lines VSL.

In the example illustrated in FIG. 1, the pixel section 100 is wired with the plurality of pixel drive line Lread installed for respective pixel row including a plurality of pixels P arranged in a horizontal direction (row direction). Each of the pixel drive lines Lread is a signal line that makes it possible to communicate a signal to drive the pixels P. The pixel drive lines Lread are configured to transmit a drive signal for reading out signals from the pixel P. It can also be said that, the pixel drive lines Lread are control lines to transmit signals for controlling the pixels P.

In addition, the pixel section 100 is wired with the vertical signal lines VSL installed for respective pixel column including a plurality of pixels P arranged in a vertical direction (column direction). The vertical signal lines VSL are signal lines that make it possible to communicate signals from the pixels P. The vertical signal lines VSL are configured to transmit signals output from the pixels P.

The vertical drive section 111 includes a shift register, an address decoder, and the like. The vertical drive section 111 is configured to drive the respective pixels P of the pixel section 100. The vertical drive section 111 generates signals to drive the pixels P and outputs the signals to the respective pixels P of the pixel section 100 via the pixel drive lines Lread.

For example, the vertical drive section 111 generates a signal for controlling a transfer transistor, a signal for controlling a reset transistor, and the like, and supplies the signals to the respective pixels P via the pixel drive lines Lread. The vertical drive section 111 is a pixel control section configured to control the respective pixels P, and may perform control in such a manner that pixel signals are read out from the respective pixels P. It is to be noted that a set of the vertical drive section 111 and the control section 115 can be said as the pixel control section.

The signal processing section 112 is configured to execute signal processing of signals of the pixels to be input. For example, the signal processing section 112 includes a load circuit section, an analog-to-digital (AD) conversion section, a horizontal selection switch, and the like. A signal outputted from each of the pixels P selected and scanned by the vertical drive section 111 is input into the signal processing section 112 through the vertical signal lines VSL. The signal processing section 112 performs signals processing such as AD conversion of signals of the pixels P or correlated double sampling (CDS).

The horizontal drive section 113 includes a shift register, an address decoder, and the like. The horizontal drive section 113 is configured to drive the horizontal selection switch of the signal processing section 112. The horizontal drive section 113 drives the respective horizontal selection switches of the signal processing section 112 in sequence while scanning them. Signals of the respective pixels P transmitted via the respective vertical signal lines VSL are subjected to signal processing by the signal processing section 112 and are output to a horizontal signal line 121 in sequence through selective scanning by the horizontal drive section 113.

The output section 114 is configured to perform signal processing on input signals and output the processed signals. The output circuit 114 performs the signal processing on signals of the pixels sequentially input from the signal processing section 112 via the horizontal signal line 121, and outputs the processed signals of the pixels. The output section 114 may perform, for example, buffering, black level adjustment, column variation correction, various kinds of digital signal processing, and the like.

The control section 115 is configured to control the respective sections of the imaging device 1. The control section 115 may receive a clock given from outside or data or the like for instructing on operation modes, and may also output data such as internal information of the imaging device 1. The control section 115 includes a timing generator configured to generate various timing signals. The control section 115 controls driving of peripheral circuits such as the vertical drive section 111, the signal processing section 112, or the horizontal drive section 113, on the basis of the various timing signals (pulse signal, clock signal, and the like) generated by the timing generator.

The terminal section 116 serves to exchange signals with the outside. The terminal section 116 includes a pad (terminal) to be used for transmitting signals to the outside, such as a pad 51 (to be described later). For example, the terminal section 116 includes an input/output pad, an input pad, an output pad, or the like. The input/output pad receives and outputs signals. The input pad receives input signals from the outside of the imaging device 1. The output pad outputs signals to the outside of the imaging device 1. In addition, the terminal section 116 may include an electric power source pad and a GND pad to supply GND voltage (ground voltage) or electric power source voltage input from the outside to respective circuits of the imaging device 1.

It is to be noted that the vertical drive section 111, the signal processing section 112, the horizontal drive section 113, the horizontal signal line 121, the output section 114, the control section 115, and the like may be installed on a single semiconductor substrate or on different semiconductor substrates. The imaging device 1 has a structure (stacked structure) where a plurality of substrates are stacked.

### Configuration of Pixel

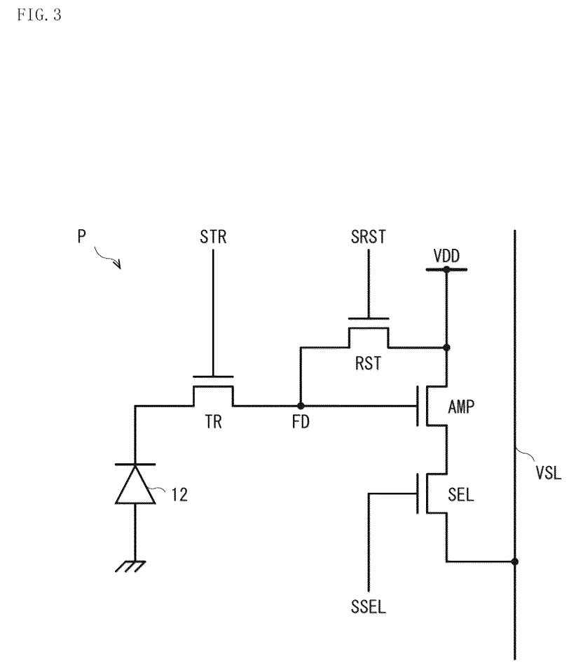

FIG. 3 is a diagram illustrating a configuration example of the pixel of the imaging device according to the embodiment. The pixel P includes a photoelectric conversion section 12, a transistor TR, a floating diffusion (FD), a transistor AMP, a transistor SEL, and a transistor RST.

Each of the transistor TR, the transistor AMP, the transistor SEL, and the transistor RST is an MOS transistor (MOSFET) having gate, source, and drain terminals. In the example illustrated in FIG. 3, the transistors TR, AMP, SEL, and RST are implemented by respective NMOS transistors. It is to be noted that the transistors of the pixel P may be implemented by PMOS transistors.

The photoelectric conversion section 12 is configured to generate electric charge through photoelectric conversion. In the example illustrated in FIG. 3, the photoelectric conversion section 12 is a photodiode (PD), and converts incident light into the electric charge. The photoelectric conversion section 12 performs the photoelectric conversion and generates the electric charge depending on amount of received light.

The transistor TR is configured to transfer the electric charge subjected to the photoelectric conversion by the photoelectric conversion section 12. As illustrated in FIG. 3, the transistor TR electrically couples or decouples the photoelectric conversion section 12 to/from the FD under the control of a signal STR. The transistor TR is a transfer transistor that may transfer, to the FD, the accumulated electric charge subjected to the photoelectric conversion by the photoelectric conversion section 12.

The FD is an accumulation section configured to accumulate the transferred electric charge. The FD may accumulate the electric charge subjected to the photoelectric conversion by the photoelectric conversion section 12. The FD can also be said as a holding section that makes it possible to hold the transferred electric charge. The FD accumulates the transferred electric charge and converts it into voltage depending on capacitance of the FD.

The transistor AMP is configured to generate and output a signal based on the electric charge accumulated in the FD. As illustrated in FIG. 3, the transistor AMP has a gate that is electrically coupled to the FD and that receives input of the voltage converted by the FD. The transistor AMP has a drain that is coupled to an electric power source line supplied with electric power source voltage VDD, and has a source that is coupled to the vertical signal line VSL via the transistor SEL. The transistor AMP is an amplification transistor that may generate a signal based on the electric charge accumulated in the FD, that is, a signal based on the voltage of FD, and may output the generated signal to the vertical signal line VSL.

The transistor SEL is configured to control output of a signal from the pixel. The transistor SEL is configured to output a signal from the transistor AMP to the vertical signal line VSL under the control of a signal SSEL. The transistor SEL is a selection transistor that may control an output timing of the signal of the pixel. It is to be noted that the transistor SEL may be installed between the transistor AMP and the electric power source line supplied with the electric power source voltage VDD. Alternatively, the transistor SEL may be omitted if necessary.

The transistor RST is configured to reset the voltage of the FD. In the example illustrated in FIG. 3, the transistor RST is configured to be electrically coupled to the electric power source line supplied with the electric power source voltage VDD, and to reset the electric charge of the pixel P. The transistor RST may reset the electric charge accumulated in the FD and reset the voltage of the FD under the control of a signal SRST. It is to be noted that the transistor RST may discharge the electric charge accumulated in the photoelectric conversion section 12, via the transistor TR. The transistor RST is a reset transistor.

The vertical drive section 111 (see FIG. 1) supplies control signals to the gates of the transistors TR, the transistors SEL, the transistors RST, and the like of the respective pixels P via the pixel drive lines Lread, and puts the transistors into an ON state (conductive state) or an OFF state (nonconductive state). The plurality of pixel drive lines Lread of the imaging device 1 includes wiring for transmitting the signal STR to control the transistors TR, wiring for transmitting the signal SSEL to control the transistors SEL, wiring for transmitting the signal SRST to control the transistors RST, and the like.

The vertical drive section 111 performs control to turn on/off the transistors TR, the transistors SEL, the transistors RST, and the like. The vertical drive section 111 controls the signal STR, the signal SSEL, the signal SRST, and the like to be input into the respective pixels P, and thereby causes the transistors AMP of the respective pixels P to output signals to the vertical signal lines VSL.

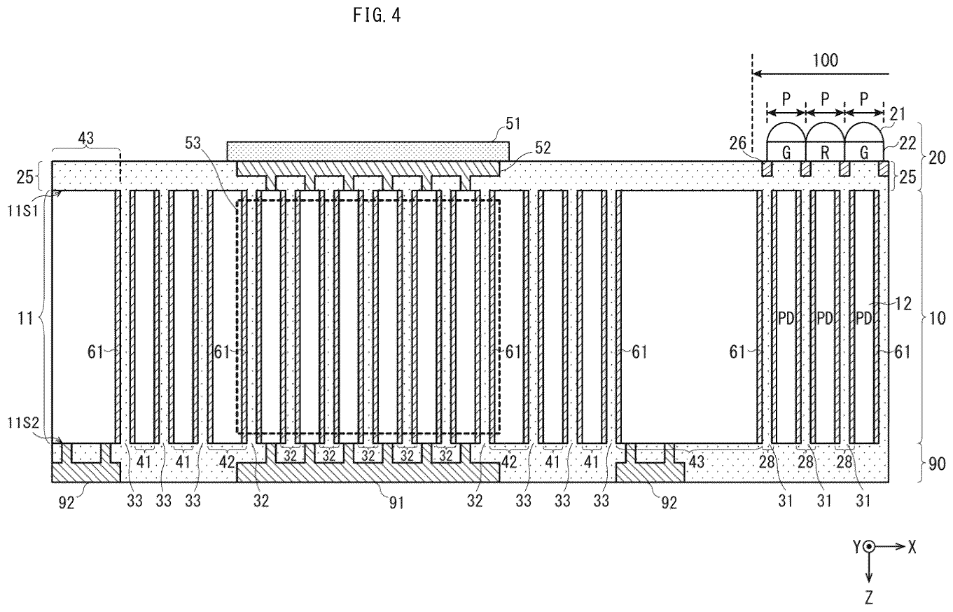

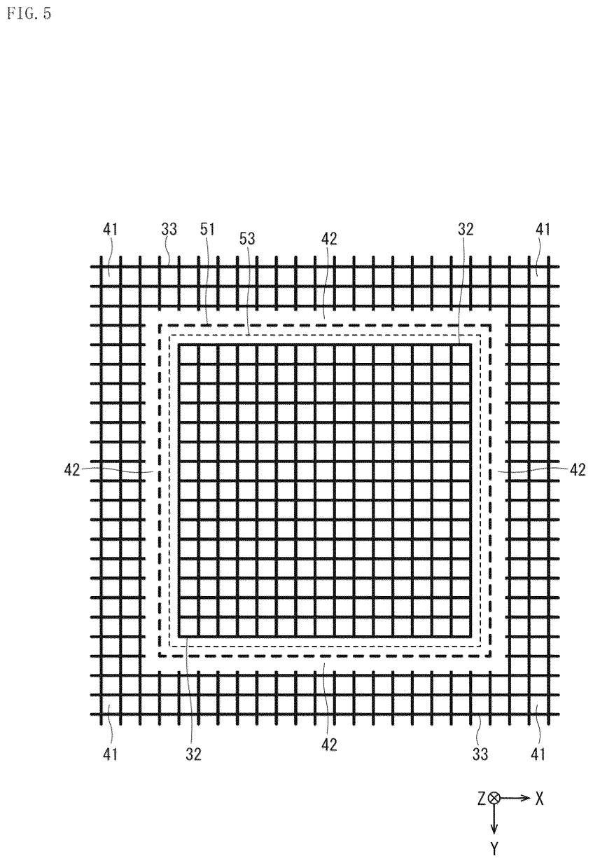

FIG. 4 is a diagram illustrating an example of a cross-sectional configuration of the imaging device according to the embodiment. FIG. 4 illustrates an example of a schematic cross-sectional configuration of the imaging device 1. In addition, FIG. 5 is a diagram illustrating an example of a planar configuration of a portion of the imaging device according to the embodiment. As illustrated in the example of FIG. 4, the imaging device 1 includes a light-receiving section 10 and a light-guiding section 20. The light-receiving section 10 includes a semiconductor layer 11 having a first surface 11S1 and a second surface 11S2 that are opposed to each other. The semiconductor layer 11 includes a semiconductor substrate (for example, silicon substrate), for example.

The light-guiding section 20 is provided on the first surface 11S1 side of the semiconductor layer 11. A wiring layer 90 is provided on the second surface 11S2 side of the semiconductor layer 11. The first surface 11S1 of the semiconductor layer 11 is a light entrance surface (light-receiving surface). The second surface 11S2 of the semiconductor layer 11 is an element forming surface on which elements such as the transistors are formed. The second surface 11S2 of the semiconductor layer 11 is provided with gate electrodes, gate oxide films, or the like.

The imaging device 1 has a structure where the light-receiving section 10, the light-guiding section 20, and the wiring layer 90 are stacked in the Z-axis direction. The light-guiding section 20 is provided on a side where light from the optical system enters, and the wiring layer 90 is provided on an opposite side from the light incident side. The imaging device 1 is a so-called back-illuminated imaging device.

The imaging device 1 is provided with the plurality of pixels P, each of which includes the photoelectric conversion section 12. As schematically illustrated in FIG. 4, the semiconductor layer 11 includes the plurality of photoelectric conversion sections 12. In the semiconductor layer 11, the plurality of photoelectric conversion sections 12 is two-dimensionally arranged. The light-receiving section 10 includes the plurality of photoelectric conversion sections 12 provided along the first surface 11S1 and the second surface 11S2 of the semiconductor layer 11. For example, the plurality of the photoelectric conversion sections 12 is buried in the semiconductor layer 11.

For example, the wiring layer 90 provided on the second surface 11S2 side of the semiconductor layer 11 includes an electrically conductive film and an insulating film, and is provided with a plurality of wirings, a via, and the like. For example, the wiring layer 90 includes wiring of two or more layers. The wiring layer 90 has a structure where the plurality of wirings is stacked with the insulating film interposed therebetween.

The wiring layer 90 is formed by using aluminium (Al), copper (Cu), tungsten (W), polysilicon (poly-Si), or the like. The insulating film is formed by using, for example, silicon oxide (SiO), silicon nitride (SiN), silicon oxynitride (SiON), or the like. The insulating film can also be said as an interlayer insulating film (interlayer insulating layer).

In the semiconductor layer 11 and the wiring layer 90, for example, the above-described transistors (transistor TR, transistor SEL, transistor RST, transistor AMP, and the like) of the respective pixels P are formed. In addition, for example, the above-described vertical drive section 111, the signal processing section 112, the horizontal drive section 113, the output section 114, and the like may also be formed in the semiconductor layer 11 and the wiring layer 90.

The light-guiding section 20 is stacked above the light-receiving section 10 in a thickness direction orthogonal to the first surface 11S1 of the semiconductor layer 11. The light-guiding section 20 includes a lens section 21 and a filter 22, and guides light incident from above toward the light-receiving section 10. The lens section 21 is an optical member that is also referred to as an on-chip lens.

For example, the lens section 21 is provided above the filter 22 for each pixel P or for a plurality of the pixels P. The lens section 21 receives light that enters from a subject via the optical system (not illustrated) such as an imaging lens. The photoelectric conversion section 12 performs the photoelectric conversion on the light incident via the lens section 21 and the filter 22.

The filter 22 is configured to selectively transmit light of a specific wavelength band among the incident light. The filter 22 is a color filter (R, G, or B), a filter that transmits infrared light, or other filters. For example, the plurality of pixels P provided in the pixel section 100 of the imaging device 1 includes a plurality of pixels (R pixels) provided with filters 22 that transmit red light (R), a plurality of pixels (G pixels) provided with filters 22 that transmit green light (G), and a plurality of pixels (B pixels) provided with filters 22 that transmit blue light (B).

In the pixel section 100, the plurality of R pixels and the plurality of G pixels and the plurality of B pixels are repeatedly arranged. The R pixels generate pixel signals of R components, the G pixels generate pixel signals of G components, and the B pixels generate pixel signals of B components. The imaging device 1 makes it possible to obtain the pixel signals of R, G, and B.

It is to be noted that the filters provided in the pixels P of the pixel section 100 are not limited to the primary color filters (RGB), but may be complementary color filters such as cyan (Cy), magenta (Mg), and yellow (Ye). In addition, it is also possible to provide a color filter corresponding to white (W), that is, a filter that transmits light of all wavelength bands among the incident light. The filters 22 may be filters that transmit infrared light.

In addition, as illustrated in FIG. 4, the imaging device 1 also includes an insulating layer 25, a light-shielding section 26, and a separation section 28 using a trench 31. The insulating layer 25 is provided between the layer where the filters 22 are provided and the layer where the photoelectric conversion sections 12 are provided. The insulating layer 25 includes a monolayer film containing one selected from the group consisting of, for example, oxide film (for example, silicon dioxide film), nitride film (for example, silicon nitride film), oxynitride film, and the like, or alternatively, the insulating layer 25 includes a stacked film containing at least two selected therefrom. The insulating layer 25 can also be said as a planarizing layer (planarizing film). Note that, it is also possible for the light-guiding section 20 to include the insulating layer 25 and the light-shielding section 26.

The light-shielding section 26 (light-shielding film) is implemented by a light-shielding member, and provided at a boundary between a plurality of adjacent pixels P. For example, the light-shielding section 26 is formed in the insulating layer 25, and is positioned above the separation section 28. For example, the light-shielding section 26 includes metal material (aluminium (Al), tungsten (W), copper (Cu), or the like) that blocks light. In the example illustrated in FIG. 4, the light-shielding section 26 is positioned at a boundary between the adjacent lens sections 21 to suppress light leaked to surrounding pixels P. It is to be noted that the light shielding section 26 may include light-absorbing material.

The separation section 28 is provided between the adjacent photoelectric conversion sections 12 to separate the photoelectric conversion sections 12 from each other. The separation sections 28 are provided to surround the photoelectric conversion sections 12 in the semiconductor layer 11. The separation sections 28 each have the trench 31 (groove section) made at a boundary between the adjacent pixels P (or photoelectric conversion sections 12).

In the example illustrated in FIG. 4, the separation section 28 has a full trench isolation (FTI) structure and is provided to penetrate the semiconductor layer 11. The trench 31 of the separation sections 28 can also be said as a through-trench. The trench 31 of the separation section 28 is formed in such a manner that the trench 31 reaches the second surface 11S2 of the semiconductor layer 11 between the plurality of adjacent photoelectric conversion sections 12 to penetrate the semiconductor layer 11. The separation section 28 can also be said as an inter-pixel separation wall or an inter-pixel separation section.

The trenches 31 of the separation sections 28 are provided to form a lattice shape in plan view in such a manner that the trench 31 surrounds each of the plurality of photoelectric conversion sections 12. The trenches 31 are provided in the lattice shape on an XY-plane. The separation section 28 is formed to surround the photoelectric conversion section 12 on all four sides, and the separation sections 28 are successively formed to surround the respective photoelectric conversion sections 12. Insides of the trenches 31 of the separation sections 28 are provided with an insulating film (insulator) such as an oxide film (for example, silicon dioxide film) or nitride film (for example, silicon nitride film), for example.

As illustrated in FIG. 4, a semiconductor region 61 is prepared on a sidewall of the trench 31. The semiconductor region 61 is a predetermined electrically conductive semiconductor region that is a semiconductor layer formed by using impurities. For example, the semiconductor region 61 is a p-type semiconductor region that is a doping layer doped with p-type impurities. The semiconductor region 61 makes it possible to suppress generation of dark current.

In addition, the imaging device 1 according to the present embodiment is provided with the pad 51, a coupling electrode 52, a via 53, a trench 32, and a trench 33. For example, as illustrated in FIG. 4, the pad 51, the coupling electrode 52, the via 53, the trench 32, the trench 33, and the like are formed in a region around the pixel section 100 in the imaging device 1.

The pad 51 is an electrode formed by using aluminium (Al), for example. The pad 51 is provided on the first surface 11S1 side, that is, a light entrance surface side (light-receiving surface side) of the semiconductor layer 11. The pad 51 is a pad electrode, and can also be said as a terminal (coupling terminal) of the imaging device 1. The imaging device 1 includes the plurality of pads 51 that are arranged therein and electrically coupled to circuit elements in the imaging device 1. It is to be noted that the pads 51 may be formed by metal material other than aluminium (Al).

For example, the imaging device 1 may include the plurality of pads 51 on the first surface 11S1 side of the semiconductor layer 11 in a region outside the pixel section 100. For example, the plurality of pads 51 of the imaging device 1 may include a pad to be used for transmitting a signal to the outside. As described above, the plurality of pads 51 includes the input/output pad that receives and outputs signals, the input pad that receives input signals from the outside of the imaging device 1, the output pad that outputs signals to the outside of the imaging device 1, and other pads.

In the example illustrated in FIG. 4, the pad 51 is formed on the insulating layer 25 and is coupled to the coupling electrode 52. It is to be noted that a portion of the pad 51 may be positioned in the insulating layer 25. It is also possible to form the pad 51 in the insulating layer 25 in such a manner that a surface (end face) of the pad 51 appears from the insulating layer 25.

The coupling electrode 52 is an electrode formed by using tungsten (W), for example. The coupling electrode 52 is provided between the pad 51 and the via 53 to electrically couple the pad 51 to the via 53. For example, the coupling electrode 52 is provided in the insulating layer 25 and electrically couples the pad 51 to the via 53. It is to be noted that the coupling electrode 52 may include another metal material. It is also possible to integrate the pad 51 and the coupling electrode 52.

The via 53 is a through-via that penetrates the semiconductor layer 11. The via 53 is formed by using electrically conductive material, for example. For example, the via 53 includes parts partitioned by the trenches 32 in the semiconductor layer 11. The via 53 is provided in such a manner that the semiconductor layer 11 is sectioned by the trenches 32 forming a lattice shape in plan view (also see FIG. 5). The trenches 32 are provided in the lattice shape on an XY-plane.

As will be described later, the via 53 includes the semiconductor regions 61 formed on the sidewalls of the trenches 32 illustrated in FIG. 4. The via 53 is provided between the pad 51 and the wiring layer 90 to electrically couple the pad 51 to wiring 91 of the wiring layer 90. The via 53 is arranged to extend in the Z-axis direction between the pad 51 and the wiring layer 90 and penetrate the semiconductor layer 11. In the example illustrated in FIG. 4, the via 53 is formed from the wiring 91 of the wiring layer 90 to the coupling electrode 52 to couple the wiring 91 of the wiring layer 90 to the coupling electrode 52.

The trench 32 is a trench (through-trench) that penetrates the semiconductor layer 11. The inside of the trench 32 is provided with an insulating film such as an oxide film (for example, silicon dioxide film) or nitride film (for example, silicon nitride film), for example. As illustrated in FIG. 4, the semiconductor region 61 is prepared on the sidewall of the trench 32.

As described above, for example, the semiconductor region 61 is a p-type semiconductor region that is a doping layer doped with p-type impurities. The via 53 includes the semiconductor region 61 as an electrically conductive region (electrically conductive section). The pad 51 is electrically coupled to the wiring 91 of the wiring layer 90 via the semiconductor region 61 that is the electrically conductive region of the via 53.

The trenches 33 are provided around the via 53 in the semiconductor layer 11. The trenches 33 are provided to penetrate the semiconductor layer 11 and surround the via 53. The insides of the trenches 33 are provided with an insulating film such as an oxide film or nitride film, for example. As an example, a silicon dioxide film is embedded in the trenches 31 of the separation sections 28 of the pixel section 100, and the trenches 32 and the trenches 33 in the region around the pixel section 100.

As illustrated in FIG. 5, the trenches 33 are provided in such a manner that the trenches 33 form a lattice shape around the via 53 in plan view. The trenches 33 are provided in the lattice shape on the XY-plane. In addition, the trenches 33 are provided outside the pad 51 in plan view. As illustrated in FIG. 4 and FIG. 5, the semiconductor layer 11 includes a plurality of semiconductor regions 41 surrounded by the respective trenches 33. The semiconductor device 1 includes the plurality of semiconductor regions 41 that surround the circumference of the via 53.

The semiconductor device 1 includes the plurality of semiconductor regions 41 that are arrayed to surround the via 53 electrically coupled to the pad 51. The plurality of semiconductor regions 41 are arranged at an interval along an outer circumference of the pad 51 in plan view. Each of the semiconductor regions 41 of the semiconductor layer 11 is a region sectioned by each trench 33 and is in an electrically floating state.

As illustrated in FIG. 4 and FIG. 5, the semiconductor layer 11 includes a semiconductor region 42 between the via 53 and the trenches 33. The semiconductor region 42 is a region surrounding the via 53 in the semiconductor layer 11. The semiconductor region 42 is sectioned by the trenches 32 and the trenches 33 and is in an electrically floating state.

In addition, as illustrated in FIG. 4, the semiconductor layer 11 includes a semiconductor region 43 outside the trenches 33. The semiconductor region 43 of the semiconductor layer 11 is electrically coupled to wiring 92 of the wiring layer 90 and is supplied with predetermined electric potential (voltage) through the wiring. For example, the semiconductor region 43 is given GND potential (ground potential) through the wiring.

As described above, in the present embodiment, the trenches 33 are provided in such a manner that the trenches 33 form the lattice shape around the via 53 in plan view. This makes it possible to reduce capacitance to be applied to the via 53. The trenches 33 forming the lattice shape around the via 53 make it possible to effectively reduce unnecessary parasitic capacitance to be applied to the via 53 and the pad 51. This makes it possible to prevent reduction in input/output (I/O) speed. Therefore, it is possible to improve transmission characteristics of signals in the pad 51 and the via 53.

In addition, as described above, the semiconductor regions 41 and 42 around the via 53 are in the electrically floating state. This makes it possible to suppress formation of large capacitance (electrostatic capacitance) for the via 53. Accordingly, it is possible to suppress signal level reduction and signal delay in the via 53, the pad 51, and the like, and to achieve high-Speed signal transmission.

Also, in the present embodiment, the trenches 31 of the pixel section 100, the trenches 32, and the trenches 33 in the region around the pixel section 100 form the same lattice shape. This makes it possible to simultaneously form the trenches 31, the trenches 32, and the trenches 33 in a manufacturing step, and it is possible to reduce the number of steps. This allows to suppress an increase in manufacturing cost of the imaging device 1.

In addition, in the present embodiment, the semiconductor regions 61 of the separation sections 28 and the semiconductor regions 61 that is the electrically conductive region of the via 53 are formed by using same impurity material. This makes it possible to form the separation sections 28 and the via 53 simultaneously, and it is possible to further reduce the number of steps.

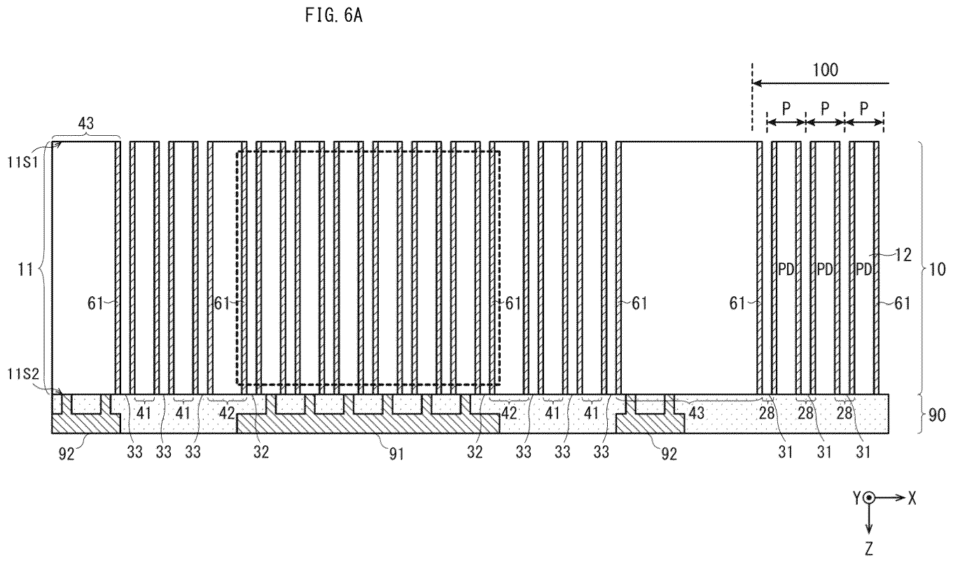

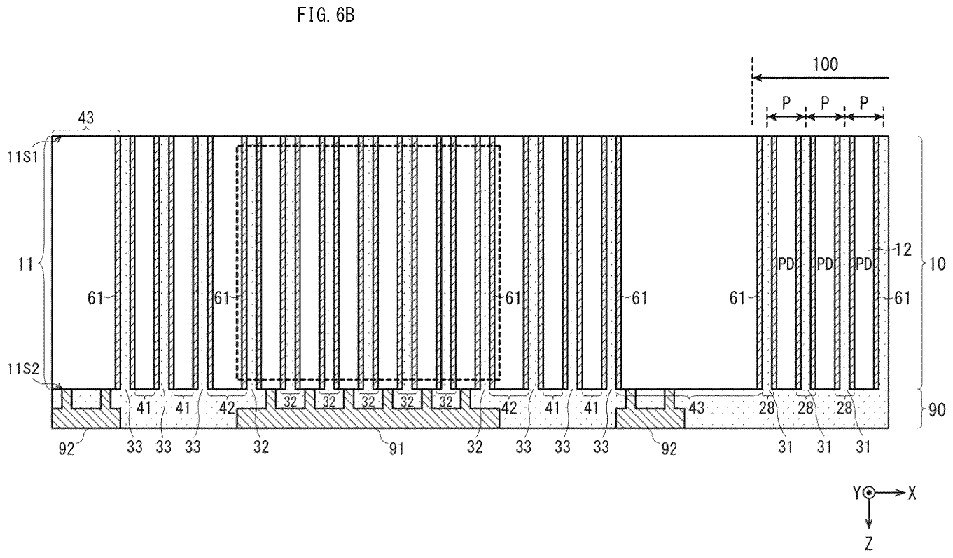

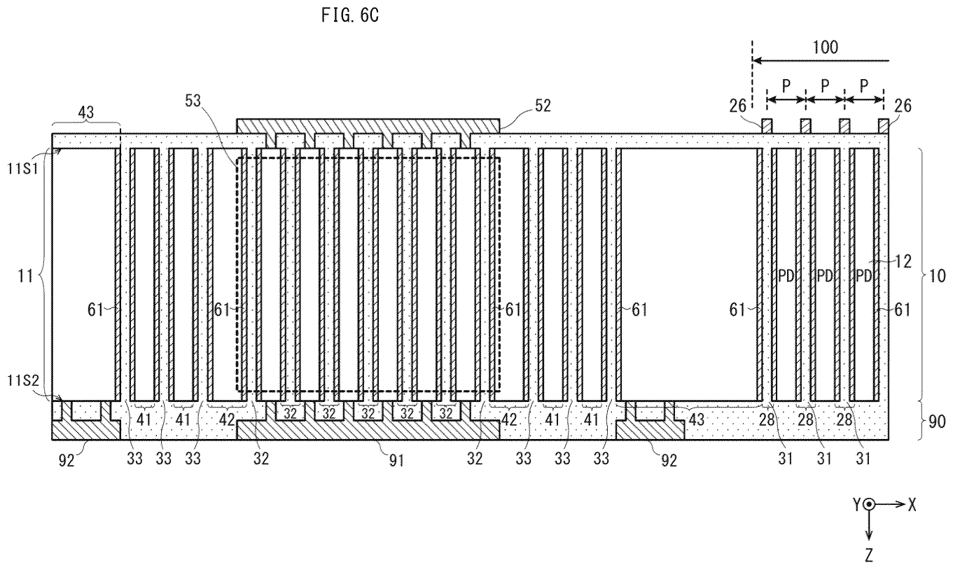

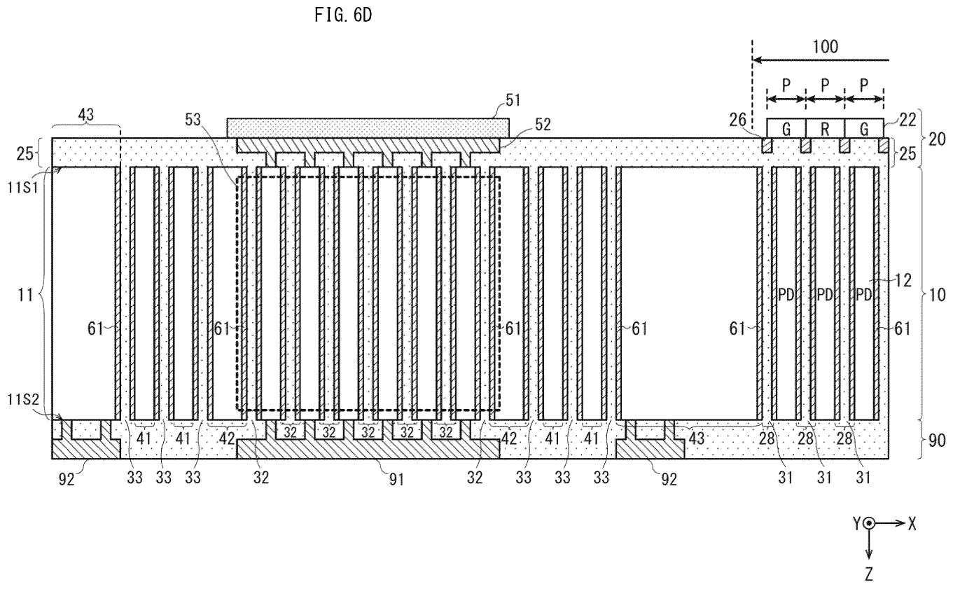

FIG. 6A to FIG. 6D are diagrams illustrating an example of a method of manufacturing the imaging device according to the embodiment. First, a chemical mechanical polishing (CMP) process is performed on a semiconductor layer 11 in which the photoelectric conversion sections 12 and the like are formed, and then wet etching is performed on insides of the trenches 31 to 32 as illustrated in FIG. 6A. Next, as illustrated in FIG. 6B, insulating members such as silicon dioxide (SiO₂) are embedded in the trenches 31 to 33.

Next, as illustrated in FIG. 6C, the coupling electrode 52 is formed in the region around the pixel section 100 and the light-shielding section 26 is formed in the pixel section 100. The coupling electrode 52 and the light-shielding section 26 are formed by using same metal material such as tungsten. Next, as illustrated in FIG. 6D, an insulating film such as a silicon dioxide (SiO₂) film is formed around the coupling electrode 52 and the light-shielding section 26, and the pad 51 and the filters 22 are sequentially formed on the insulating layer 25.

The pad 51 is formed on the coupling electrode 52, and the filters 22 are formed on the insulating layer 25 including the light-shielding section 26. Next, the lens section 21 is formed on the filters 22. By using the manufacturing method as described above, it is possible to manufacture the imaging device 1 illustrated in FIG. 4 and the like. It is to be noted that the above-described manufacturing method is a mere example, and other manufacturing methods may be adopted.

### Actions and Effects

The photodetection device according to the present embodiment includes: a semiconductor layer (semiconductor layer 11) including a plurality of photoelectric conversion sections (photoelectric conversion sections 12) that performs photoelectric conversion on light; a pad (pad 51) that is provided on the first surface side of the semiconductor layer; a via (via 53) that penetrates the semiconductor layer and is electrically coupled to the pad; and a first trench (trench 33) that is provided in such a manner that the first trench penetrates the semiconductor layer around the via to surround the via. The first trench is provided in such a manner that the first trenches from a lattice shape around the via in plan view.

The photodetection device (imaging device 1) according to the present embodiment includes the trenches 33 provided in such a manner that the trenches 33 form the lattice shape around the via 53 in plan view. This makes it possible to reduce unnecessary parasitic capacitance to be applied to the via 53. It is possible to provide the photodetection device that makes it possible to reduce such parasitic capacitance.

Next, modifications of the present disclosure will be described. Hereinafter, structural elements that are similar to the above-described embodiment will be denoted with the same reference signs as the above-described embodiment, and repeated description will be omitted appropriately.

### 2. Modifications

### (2-1. First Modification)

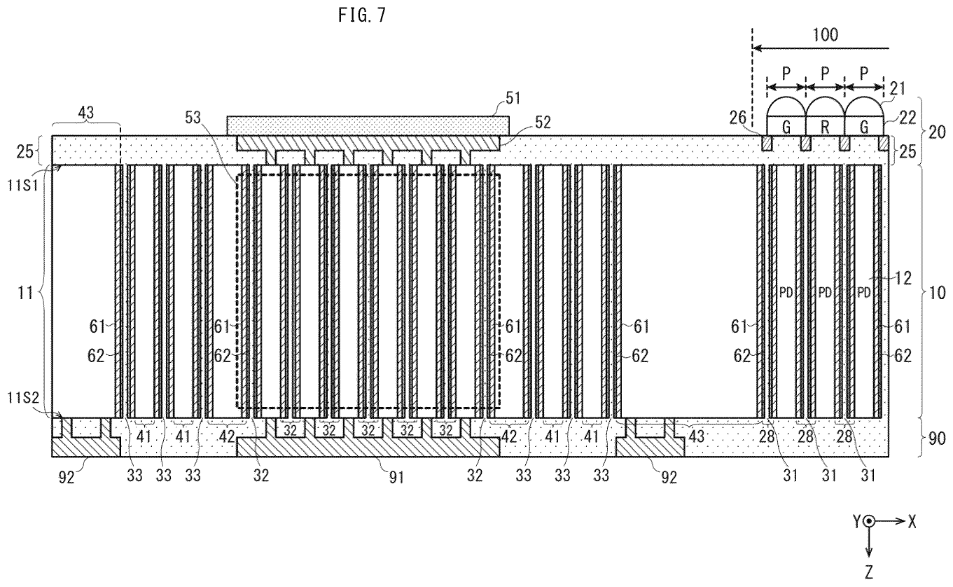

In the above-described embodiment, the configuration example of the photodetection device 1 has been described. However, the configuration of the photodetection device (imaging device 1) is not limited thereto. FIG. 7 is a diagram illustrating an example of a cross-sectional configuration of an imaging device according to the first modification. As illustrated in FIG. 7, the imaging device 1 may include a pinning film 62. For example, the pinning film 62 includes a metal compound (metal oxide, metal nitride, or the like) and can also be said as a metal compound layer.

The pinning film 62 is a film with fixed electric charge and is formed by using a high-dielectric body. For example, the pinning film 62 is a film with negative fixed electric charge and suppress generation of dark current on an interface of the semiconductor layer 11. The pinning film 62 can also be said as a fixed electric charge film.

For example, the pinning film 62 includes at least one of oxides of chemical elements such as hafnium (Hf), zirconium (Zr), aluminium (Al), titanium (Ti), tantalum (Ta), magnesium (Mg), yttrium (Y), or lanthanoid (La). The pinning film 62 may be provided on the respective sidewalls of the trenches 31 to 33.

In the example illustrated in FIG. 7, the trenches 31 to 33 are provided with the pinning films 62 in such a manner that the pinning films 62 cover the sidewalls of the trenches 31 to 33. The pinning films 62 are arranged next to the semiconductor regions 61. The via 53 includes the pinning films 62 as portions of the electrically conductive region (electrically conductive section). The pad 51 makes it possible to electrically couple to the wiring 91 of the wiring layer 90 via the pinning films 62 that are the electrically conductive regions of the via 53. Also in the present modification, it is possible to achieve effects that are similar to the above-described embodiment.

It is to be noted that, in the example illustrated in FIG. 7, the via 53 includes the plurality of semiconductor regions 61 and the pinning films 62 as the electrically conductive regions. The pad 51 is electrically coupled to the wiring 91 of the wiring layer 90 via the plurality of semiconductor regions 61 and the pinning films 62. For example, the pinning films 62 with the negative fixed electric charge makes it possible to increase hole concentration in regions adjacent to the pinning films 62, and this makes it possible to decrease resistance of the via 53.

### (2-2. Second Modification)

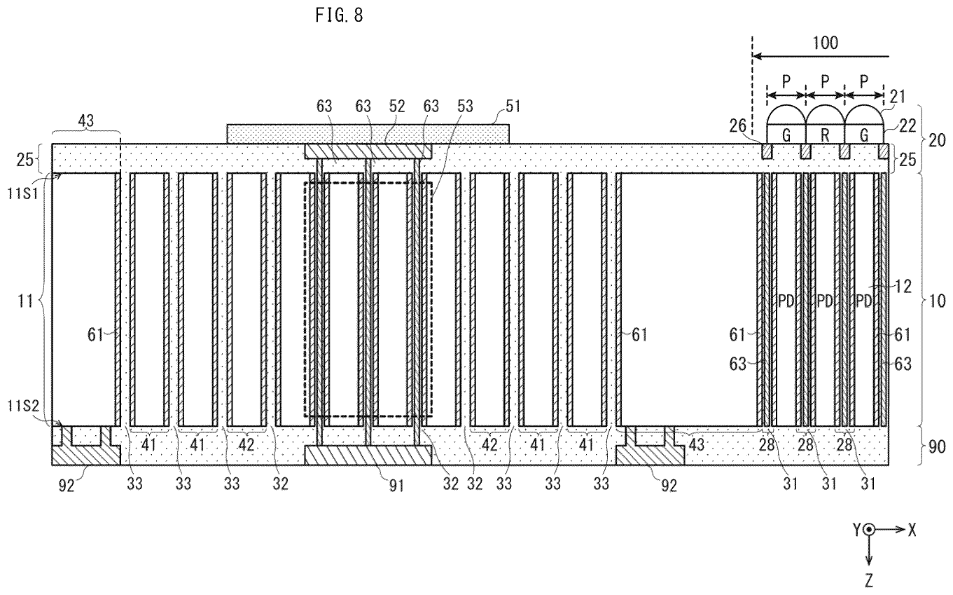

FIG. 8 is a diagram illustrating an example of a cross-sectional configuration of an imaging device according to the second modification. As illustrated in FIG. 8, a metal film 63 may be embedded in the trenches 31 of the separation sections 28. The metal film 63 includes metal material such as tungsten (W), aluminium (Al), or cobalt (Co). The metal films 63 provided inside the trenches 31 makes it possible to suppress light leaked to surrounding pixels P.

Metal material embedded in the trench 32 may be the same as the metal material embedded in the trenches 31. In the example illustrated in FIG. 8, the metal films 63 are also provided inside the trenches 32 below the coupling electrode 52 in a way similar to the trenches 31. In this case, the via 53 includes the metal films 63 as portions of the electrically conductive region (electrically conductive section). The pad 51 makes it possible to electrically couple to the wiring 91 of the wiring layer 90 via the metal films 63 that are the electrically conductive regions of the via 53. Also in the present modification, it is possible to achieve effects that are similar to the above-described embodiment.

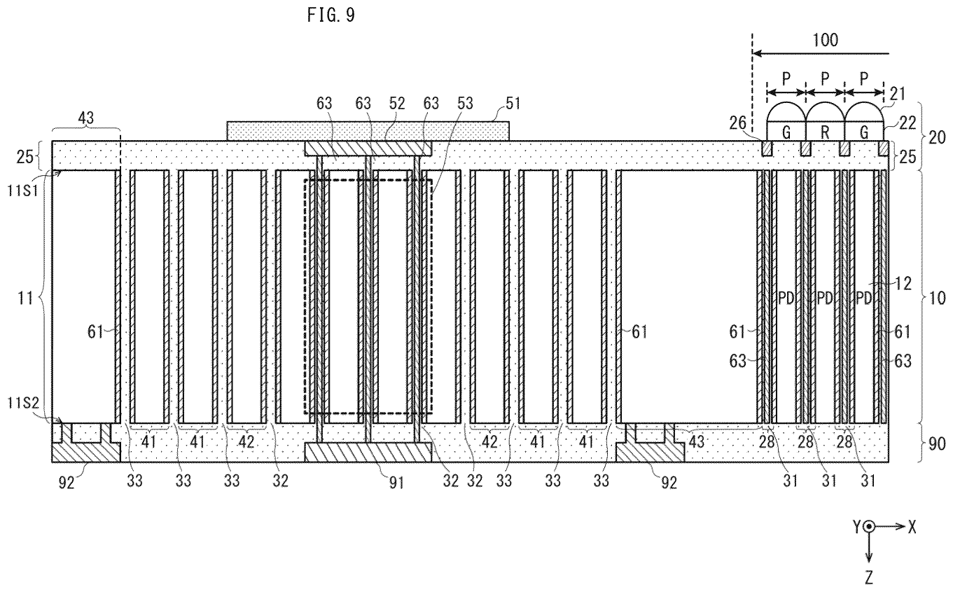

It is to be noted that, in the example illustrated in FIG. 8, pitch between the trenches 32 or 33 (arrangement intervals between trenches 32 or 33) are substantially the same as pitch between the trenches 31 (arrangement intervals between trenches 31). As illustrated in an example of FIG. 9, the pitch between the trenches 32 or 33 may be different from the pitch between the trenches 31. For example, the pitch between the trenches 32 or 33 in the region around the pixel section 100 may be wider than the pitch between the trenches 31 of the pixel section 100. In the example of FIG. 9, the pitch between the trenches 32 or 33 in the X-axis direction and in the Y-axis direction is wider than the pitch between the trenches 31.

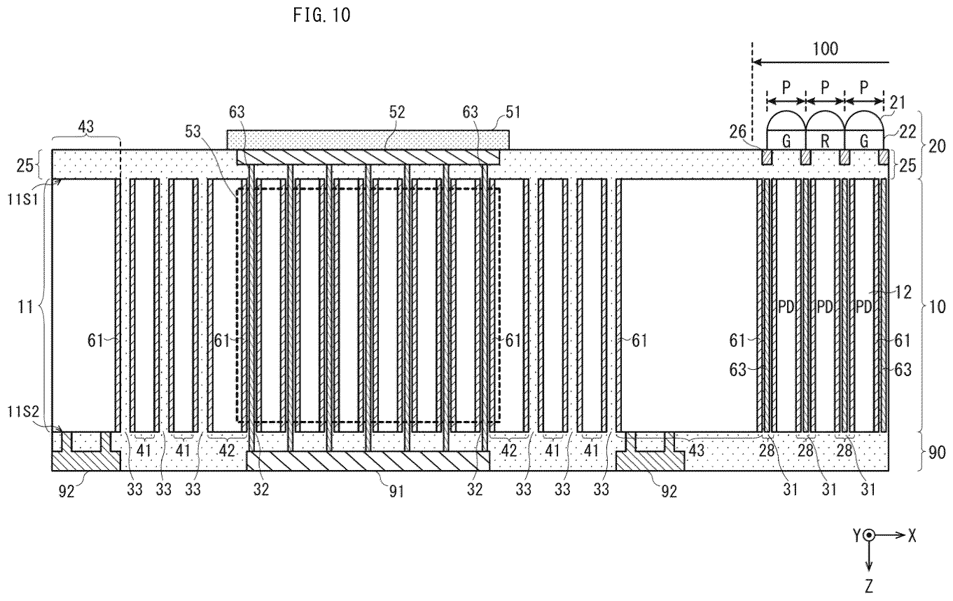

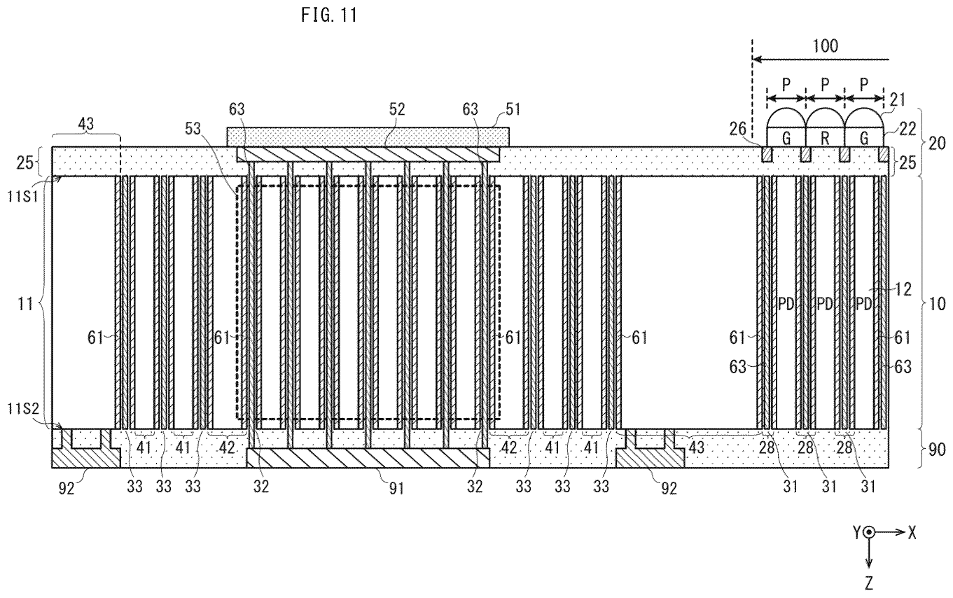

In addition, as illustrated in an example of FIG. 10, the metal films 63 may be provided inside the more trenches 32. This makes it possible to decrease the resistance of the via 53. As illustrated in FIG. 10, the via 53 may be implemented by the metal films 63 embedded in the respective trenches below the pad51. This makes it possible to decrease the resistance of the via 53. Note that, as illustrated in FIG. 11, it is also possible to provide the metal films 63 also inside the trenches 33 around the via 53.

### 3. Application Example

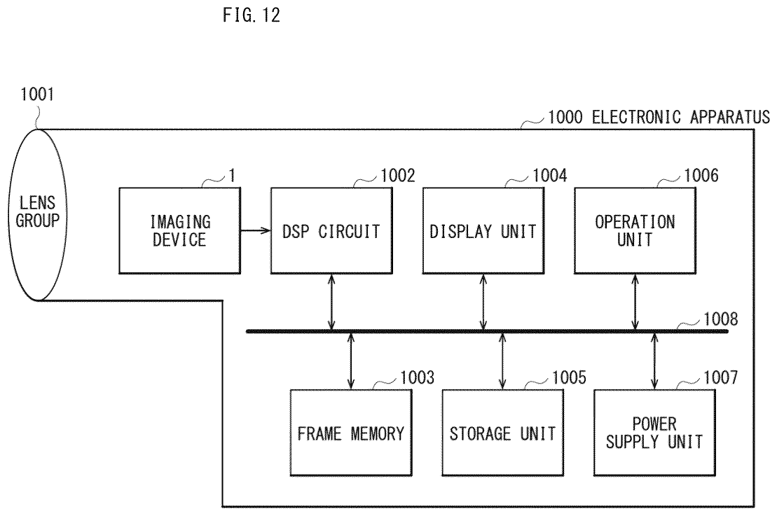

The above-described imaging device 1 or the like are applicable to any type of electronic apparatus having an imaging function, such as a camera system of a digital still camera or a video camera, or a mobile phone having an imaging function. FIG. 12 illustrates a schematic configuration of an electronic apparatus 1000.

The electronic apparatus 1000 includes, for example, a lens group 1001, the imaging device 1, a digital signal processor (DSP) circuit 1002, a frame memory 1003, a display unit 1004, a storage unit 1005, an operation unit 1006, and a power supply unit 1007. They are coupled to each other through a bus line 1008.

The lens group 1001 takes in incident light (image light) from a subject and forms an image on an imaging surface of the imaging device 1. The imaging device 1 converts the amount of incident light formed as an image on the imaging surface by the lens group 1001 into electric signals in units of pixels and supplies the DSP circuit 1002 with the electric signals as pixel signals.

The DSP circuit 1002 is a signal processing circuit that processes a signal supplied from the imaging device 1. The DSP circuit 1002 outputs image data that is obtained by processing the signals from the imaging device 1. The frame memory 1003 temporarily holds the image data processed by the DSP circuit 1002 in units of frames.

The display unit 1004 includes, for example, a panel-type display device such as a liquid crystal panel or an organic electroluminescence (EL) panel and records the image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the storage unit 1005, and the operation unit 1006 with various kinds of power for operations of these supply targets.

### 4. Application Example

### (Example of Application to Mobile Object)

The technology according to the present disclosure (present technology) is applicable to various products. For example, the technology according to the present disclosure may be implemented as a device that is installed on any kind of mobile objects including vehicles, electric vehicles, hybrid electric vehicles, motorcycles, bicycles, personal mobilities, airplanes, drones, ships, robots, and the like.

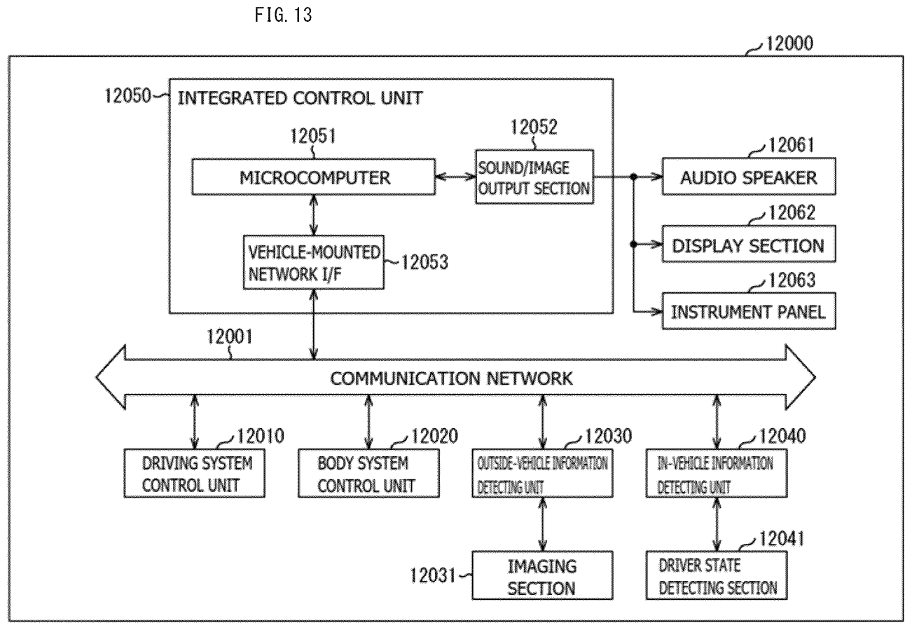

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

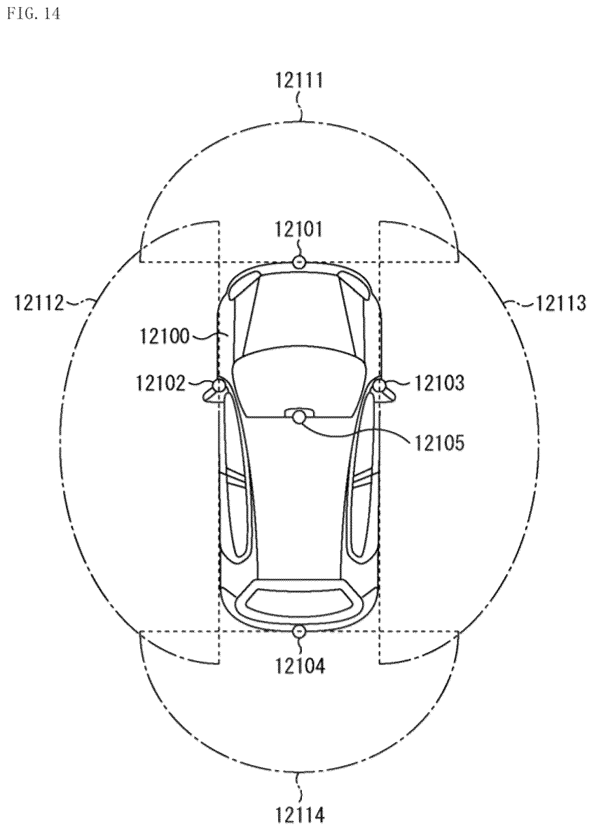

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile object control system to which the technology according to the present disclosure is applicable has been described above. The technology according to the present disclosure is applicable to the imaging section 12031 among the above-described components. Specifically, for example, the imaging device 1 and the like is applicable to the imaging section 12031. It is possible to appropriately transmit signals by applying the technology according to the present disclosure to the imaging section 12031. Therefore, it is possible to perform high-precision control utilizing the captured image in the mobile object control system.

### (Example of Application to Endoscopic Surgery System)

The technology according to the present disclosure (present technology) is applicable to various products. For example, the technology according to the present disclosure is applicable to an endoscopic surgery system.

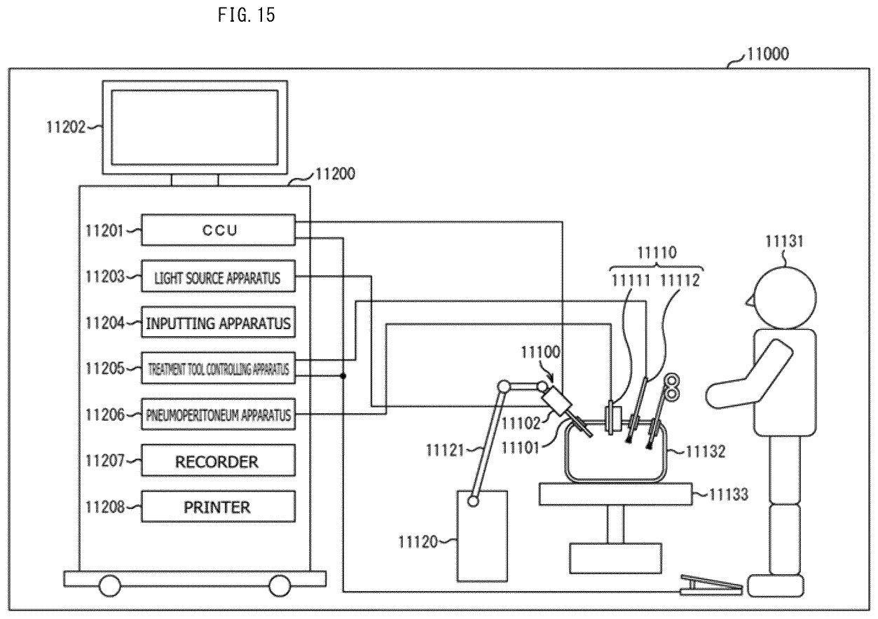

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

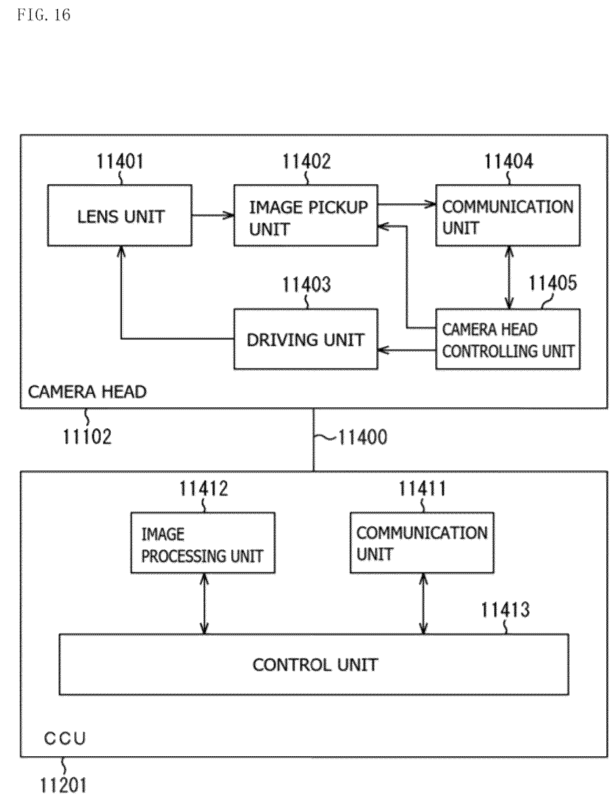

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure is applicable has been described above. The technology according to the present disclosure is favorably applicable to the image pickup unit 11402 provided to the camera head 11102 of the endoscope 11100 among the above-described components. The application of the technology according to the present disclosure to the image pickup unit 11402 makes it possible to sensitize the image pickup unit 11402 and provide the high-resolution endoscope 11100.

The present disclosure has been described above with reference to the embodiment, modifications, application examples, and further application examples. However, the present technology is not limited thereto, and various kinds of modifications thereof can be made. For example, the above modifications have been described as the modifications of the embodiment. In addition, structural elements according to the respective modifications can be used in combination as appropriate.

A photodetection device according to an embodiment of the present disclosure includes: a semiconductor layer including a plurality of photoelectric conversion sections that performs photoelectric conversion on light; a pad that is provided on a first surface side of the semiconductor layer; a via that penetrates the semiconductor layer and is electrically coupled to the pad; and a first trench that is provided in such a manner that the first trench penetrates the semiconductor layer around the via to surround the via. The first trench is provided in such a manner that the first trenches form a lattice shape around the via in plan view. This makes it possible to reduce unnecessary parasitic capacitance to be applied to the via. It is possible to provide the photodetection device that makes it possible to reduce such parasitic capacitance.

It is to be noted that the effects described herein are only for illustrative purposes and there may be other effects. In addition, the present technology may be configured as follows.

(1)

A photodetection device including:

a semiconductor layer including a plurality of photoelectric conversion sections that performs photoelectric conversion on light;

a pad that is provided on a first surface side of the semiconductor layer;

a via that penetrates the semiconductor layer and is electrically coupled to the pad; and

a first trench that is provided in such a manner that the first trench penetrates the semiconductor layer around the via to surround the via,

in which the first trench is provided in such a manner that the first trenches forms a lattice shape around the via in plan view.

(2)

The photodetection device according to (1), in which

the semiconductor layer includes a plurality of first semiconductor regions surrounded by the respective first trenches provided around the via, and

the plurality of first semiconductor regions are arrayed to surround a circumference of the via.

(3)

The photodetection device according to (2), in which the first semiconductor region is in an electrically floating state.

(4)

The photodetection device according to any one of (1) to (3), in which

the semiconductor layer includes a second semiconductor region between the via and the first trenches, and

the second semiconductor region is in the electrically floating state.

(5)

The photodetection device according to any one of (1) to (4), in which the first trench is provided outside the pad in plan view. (6)

The photodetection device according to any one of (1) to (5), including

a second trench that is adjacent to the via and penetrates the semiconductor layer,

in which the via includes a semiconductor region doped with an impurity on a sidewall of the second trench.

(7)

The photodetection device according to any one of (1) to (6), including

a second trench that is adjacent to the via and penetrates the semiconductor layer,

in which the via includes a pinning film provided on a sidewall of the second trench.

(8)

The photodetection device according to any one of (1) to (7), including

a second trench that is provided with the via and penetrates the semiconductor layer,

in which the via includes metal material provided in the second trench.

(9)

The photodetection device according to any one of (1) to (8), including

a third trench that is provided in such a manner that the third trench penetrates the semiconductor layer between a plurality of the adjacent photoelectric conversion sections to surround each of the plurality of photoelectric conversion sections.

(10)

The photodetection device according to (9), in which the first trenches and the third trenches form a same lattice shape in plan view.

(11)

The photodetection device according to (9) or (10), including

a second trench that is adjacent to the via and penetrates the semiconductor layer,

in which the second trenches and the third trenches form a same lattice shape in plan view.

(12)

The photodetection device according to any one of (9) to (11), including:

a second trench that is adjacent to the via and penetrates the semiconductor layer; and

a semiconductor region that is provided on both a sidewall of the second trench and a sidewall of the third trench and is doped with an impurity.

(13)

The photodetection device according to any one of (9) to (12), including:

a second trench that is adjacent to the via and penetrates the semiconductor layer; and

a pinning film that is provided on both a sidewall of the second trench and a sidewall of the third trench.

(14)

The photodetection device according to any one of (9) to (13), including

a second trench that is provided with the via and penetrates the semiconductor layer,

in which the second trench and the third trench include same metal material that is embedded therein.

(15)

The photodetection device according to any one of (9) to (14), in which the photodetection device has a backside illumination structure.

(16)

The photodetection device according to any one of (9) to (15), including:

a lens that is provided on the first surface side of the semiconductor layer; and

a wiring layer that is provided on a second surface side that is an opposite side from the first surface of the semiconductor layer.

(17)

An electronic apparatus including:

an optical system; and

a photodetection device that receives light passed though the optical system,
in which the photodetection device includes
   a semiconductor layer including a plurality of photoelectric conversion sections that performs photoelectric conversion on light,
   a pad that is provided on a first surface side of the semiconductor layer,
   a via that penetrates the semiconductor layer and is electrically coupled to the pad, and
   a first trench that is provided in such a manner that the first trench penetrates the semiconductor layer around the via to surround the via, and
the first trench is provided in such a manner that the first trenches form a lattice shape around the via in plan view.

The present application claims the benefit of Japanese Priority Patent Application JP2022-144731 filed with the Japan Patent Office on Sep. 12, 2022, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A photodetection device, comprising:
a semiconductor layer including a plurality of photoelectric conversion sections that performs photoelectric conversion on light;
a pad that is provided on a first surface side of the semiconductor layer;
a via that penetrates the semiconductor layer and is electrically coupled to the pad; and
a first trench that is provided in such a manner that the first trench penetrates the semiconductor layer around the via to surround the via,
wherein the first trench is provided in such a manner that the first trenches forms a lattice shape around the via in plan view.

2. The photodetection device according to claim 1, wherein
the semiconductor layer includes a plurality of first semiconductor regions surrounded by the respective first trenches provided around the via, and
the plurality of first semiconductor regions are arrayed to surround a circumference of the via.

3. The photodetection device according to claim 2,
wherein the first semiconductor region is in an electrically floating state.

4. The photodetection device according to claim 1, wherein
the semiconductor layer includes a second semiconductor region between the via and the first trenches, and
the second semiconductor region is in the electrically floating state.

5. The photodetection device according to claim 1, wherein the first trench is provided outside the pad in plan view.

6. The photodetection device according to claim 1, comprising
a second trench that is adjacent to the via and penetrates the semiconductor layer,
wherein the via includes a semiconductor region doped with an impurity on a sidewall of the second trench.

7. The photodetection device according to claim 1, comprising
a second trench that is adjacent to the via and penetrates the semiconductor layer,
wherein the via includes a pinning film provided on a sidewall of the second trench.

8. The photodetection device according to claim 1, comprising
a second trench that is provided with the via and penetrates the semiconductor layer,
wherein the via includes metal material provided in the second trench.

9. The photodetection device according to claim 1, comprising
a third trench that is provided in such a manner that the third trench penetrates the semiconductor layer between a plurality of the adjacent photoelectric conversion sections to surround each of the plurality of photoelectric conversion sections.

10. The photodetection device according to claim 9, wherein the first trenches and the third trenches form a same lattice shape in plan view.

11. The photodetection device according to claim 9, comprising
a second trench that is adjacent to the via and penetrates the semiconductor layer,
wherein the second trenches and the third trenches form a same lattice shape in plan view.

12. The photodetection device according to claim 9, comprising:
a second trench that is adjacent to the via and penetrates the semiconductor layer; and
a semiconductor region that is provided on both a sidewall of the second trench and a sidewall of the third trench and is doped with an impurity.

13. The photodetection device according to claim 9, comprising:
a second trench that is adjacent to the via and penetrates the semiconductor layer; and
a pinning film that is provided on both a sidewall of the second trench and a sidewall of the third trench.

14. The photodetection device according to claim 9, comprising
a second trench that is provided with the via and penetrates the semiconductor layer,
wherein the second trench and the third trench include same metal material that is embedded therein.

15. The photodetection device according to claim 1, wherein the photodetection device has a backside illumination structure.

16. The photodetection device according to claim 1, comprising:
a lens that is provided on the first surface side of the semiconductor layer; and
a wiring layer that is provided on a second surface side that is an opposite side from the first surface of the semiconductor layer.

17. An electronic apparatus, comprising:
an optical system; and
a photodetection device that receives light passed though the optical system,
wherein the photodetection device includes
a semiconductor layer including a plurality of photoelectric conversion sections that performs photoelectric conversion on light,
a pad that is provided on a first surface side of the semiconductor layer,
a via that penetrates the semiconductor layer and is electrically coupled to the pad, and
a first trench that is provided in such a manner that the first trench penetrates the semiconductor layer around the via to surround the via, and
the first trench is provided in such a manner that the first trenches form a lattice shape around the via in plan view.
